(19) United States
(12) Patent Application Publication
(10) Pub. No.: US 2026/0271347 A1
(43) Pub. Date: Sep. 10, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Keng-Ying LIAO, Tainan City (TW); Po-Zen CHEN, Tainan City (TW); Chih Wei SUNG, Kaohsiung City (TW); Hsien-Kai TSENG, New Taipei City (TW); Chenchia HUNG, Kaohsiung City (TW); Chen-Chi HSIAO, Taipei City (TW); Guan-Qi CHEN, Kaohsiung City (TW)

(73) Assignee: TAIWAN SEMICONDUCTOR MANUFACTURING COMPANY, LTD., Hsinchu (TW)

(21) Appl. No.: 19/072,504

(22) Filed: Mar. 6, 2025

(51) Int. Cl. H10D 62/10; H10D 86/00

(52) U.S. Cl. CPC H10D 62/102; H10D 86/201

(57) ABSTRACT

A semiconductor device includes a substrate. The substrate includes a base semiconductor layer, an insulator layer over the base semiconductor layer, and an active semiconductor layer over the base semiconductor layer, wherein the active semiconductor layer has an active region. A deep trench isolation (DTI) structure is in the substrate and adjacent to the active region, wherein in a cross-sectional view, a sidewall of the DTI structure comprises a first protrusion portion and a second protrusion portion below the first protrusion portion.

### BACKGROUND

Modern day integrated chips comprise millions or billions of semiconductor devices formed on a semiconductor substrate (e.g., silicon). Integrated chips (ICs) may use many different types of semiconductor devices, depending on an application of an IC. To reduce the area of the IC, the semiconductor devices may be formed in close proximity to one another. To prevent interference amongst the semiconductor devices, techniques and/or features for device isolation in ICs are being researched. Among other things, deep trench isolation structures are a promising candidate to provide electrical isolation amongst semiconductor devices to improve device performance without sacrificing a large area on the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 11 illustrate a method in various stages of forming a semiconductor device in accordance with some embodiments of the present disclosure.

FIGS. 12 to 15 illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

In some applications, more than one semiconductor device may be integrated onto a same substrate. However, current leakage, cross-talk between the semiconductor devices, and/or eventual device performance degradation may become difficult to prevent as device size decreases and voltage operating conditions increase (e.g., greater than 100 Volts). To mitigate current leakage and device performance degradation, in some embodiments, for example, multiple semiconductor devices may be integrated on a silicon-on-insulator (SOI) substrate comprising an insulator layer between an active semiconductor layer and a base semiconductor layer. In other embodiments, to arrange semiconductor devices even closer to one another and provide more reliable device isolation, isolation structures may be formed to electrically separate the semiconductor devices from one another. For example, a deep trench isolation (DTI) structure filled with a conductive material, such as polysilicon, may be formed to continuously surround each of the semiconductor devices. The DTI structure may extend into the base semiconductor layer such that the polysilicon contacts the base semiconductor layer of the SOI substrate. The conductive material may be grounded to the base semiconductor layer of the SOI substrate during operation in order to achieve electrical isolation and improve device performance. However, due to corona discharge, the SOI substrate may suffer from high voltage leakage at the bottom corner edge of the active semiconductor layer, which will inversely affect the device performance. Accordingly, embodiments of the present disclosure provide a structure and a formation method thereof to address the above issues.

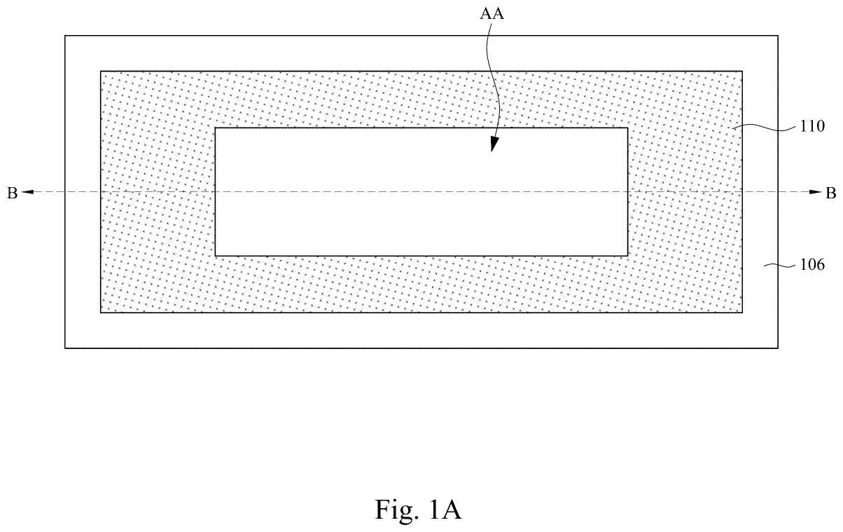

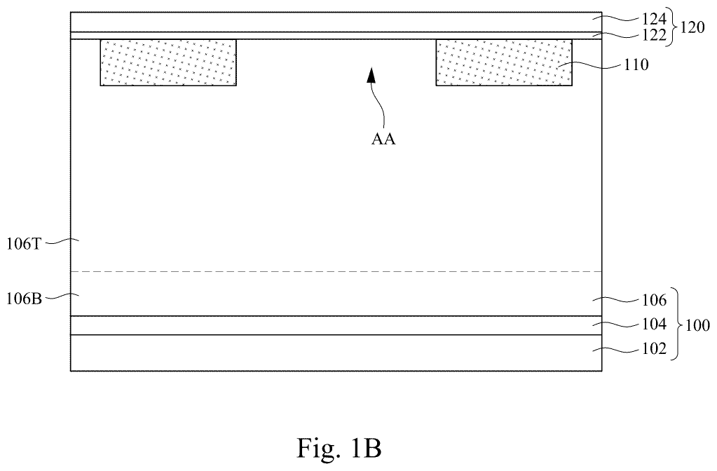

FIGS. 1A to 11 illustrate a method in various stages of forming a semiconductor device in accordance with some embodiments of the present disclosure. In greater detail, FIGS. 1A, 2A, and 10A are top views of a semiconductor device, and FIGS. 1B, 2B, 3-9, and 10B are cross-sectional views of a semiconductor device. Although FIGS. 1A to 11 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 1A and 1B, in which FIG. 1A is a top view of a semiconductor device, and FIG. 1B is a cross-sectional view along line B-B of FIG. 1A. It is noted that some elements of FIG. 1B are not illustrated in FIG. 1A for clarity. Shown there is a silicon-on-insulator (SOI) substrate 100. In some embodiments, the SOI substrate 100 includes a base semiconductor layer 102, an active semiconductor layer 106 arranged over the base semiconductor layer 102, and an insulator layer 104 arranged between the active semiconductor layer 106 and the base semiconductor layer 102. In some embodiments, the base semiconductor layer 102 comprises a monocrystalline semiconductor material (e.g., silicon, germanium, etc.). Similarly, the active semiconductor layer 106 may also comprise a semiconductor material, such as for example, silicon, germanium, or the like. In some embodiments, the base semiconductor layer 102 may include an N-type semiconductor material, for example. In some other embodiments, the SOI substrate 101 may be some other type of substrate and comprise any type of semiconductor body (e.g., silicon/CMOS bulk, SiGe, etc.). In some embodiments, the insulator layer 104 may include a dielectric material, such as silicon oxide, silicon nitride, or the like. In some embodiments, the thickness of the insulator layer 104 is about 0.1 μm to about 0.5 μm (e.g., 0.3 μm). In some embodiments, the thickness of the active semiconductor layer 106 is about 4.0 μm to about 5.0 μm (e.g., 4.5 μm). In some embodiments, the active semiconductor layer 106 may be a doped with n-type dopants or p-type dopants. In some embodiments, the active semiconductor layer 106 may include a top portion 106T and a bottom portion 106B below the top portion 106T, in which the bottom portion 106B may include a higher dopant concentration than the top portion 106T.

A shallow trench isolation (STI) structure 110 is formed in the active semiconductor layer 106 of the SOI substrate 100. In some embodiments, the STI structure 110 may include a rectangular ring shape top profile as shown in FIG. 1A, and the STI structure 110 may surround an active region AA of the active semiconductor layer 106. In some embodiments, the STI structure may each comprise an insulator and/or dielectric material, such as, for example, silicon oxide, silicon nitride, silicon oxynitride, the like, or combinations thereof. The STI structure 110 may be formed by, for example, patterning the active semiconductor layer 106 of the SOI substrate 100 to form a trench in the active semiconductor layer 106, filling the trench with one or more dielectric materials, and then performing a planarization process (e.g., CMP) to remove excess dielectric materials until the active semiconductor layer 106 is exposed.

A hard mask structure 120 is then formed over the active semiconductor layer 106 of the SOI substrate 100 and covering the STI structure 110. In some embodiments, the hard mask structure 120 may include a first dielectric layer 122 and a second dielectric layer 124 over the first dielectric layer 122, in which the first dielectric layer 122 and the second dielectric layer 124 are made of different dielectric materials. For example, the first dielectric layer 122 may be silicon nitride, and the second dielectric layer 124 may be silicon oxide. In some embodiments, the second dielectric layer 124 is thicker than the first dielectric layer 122. In some embodiments, the thickness of the first dielectric layer 122 may be about 0.15 μm and to about 0.2 μm, such as 0.16 μm. On the other hand, the thickness of the second dielectric layer 124 may be about 0.5 μm to about 1 μm, such as 0.6 μm. It will be appreciated that other values are also within the scope of the disclosure. In some embodiments, the first dielectric layer 122 and the second dielectric layer 124 may be formed by one or more deposition techniques (e.g., physical vapor deposition (PVD), chemical vapor deposition (CVD), PE-CVD, atomic layer deposition (ALD), sputtering, etc.).

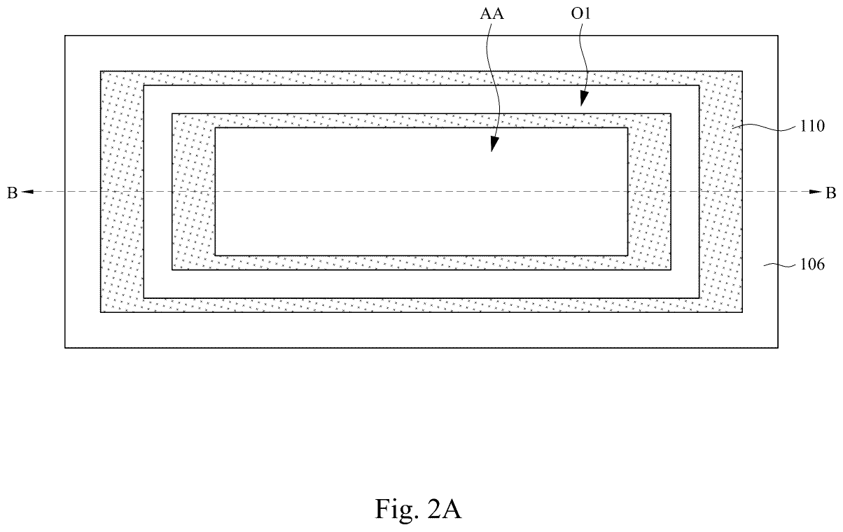

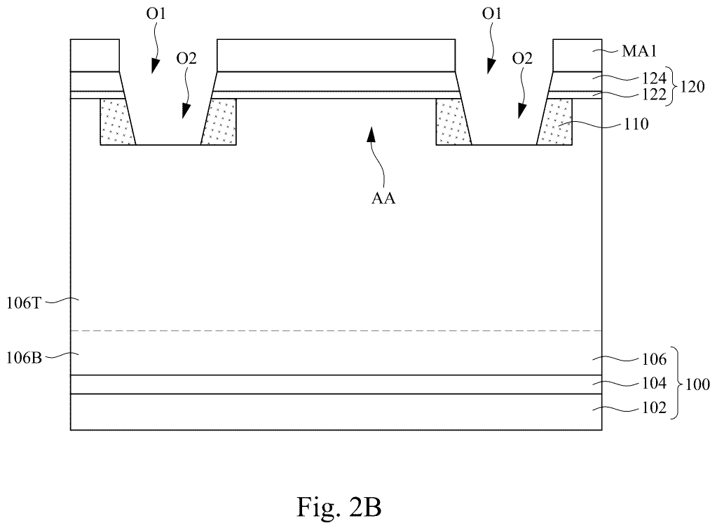

Reference is made to FIGS. 2A and 2B, in which FIG. 2A is a top view of a semiconductor device, and FIG. 2B is a cross-sectional view along line B-B of FIG. 2A. It is noted that some elements of FIG. 2B are not illustrated in FIG. 2A for clarity. A patterned mask MA1 is formed over the hard mask structure 120. The patterned mask MA1 comprises an opening O1 that directly overlies the STI structure 110. In some embodiments, the opening O1 has a width W1 that is less than a width W2 of the STI structure 110. In some embodiments, the patterned mask MA1 comprises a photoresist material deposited via a spin coating process. The patterned mask MA1 may then be selectively exposed to a radiation according to a photomask. The radiation modifies a solubility of exposed regions within the patterned mask MA1 to define soluble regions. The patterned mask MA1 is subsequently developed to define the opening O1 after removing the soluble regions.

A first removal process is performed to remove portions of the hard mask structure 120 and the STI structure 110 through the opening O1 of the patterned mask MA1, so as to form an opening O2 in the hard mask structure 120 and the STI structure 110, in which the opening O2 may expose portions of the active semiconductor layer 106 of the SOI substrate 100. In some embodiments, the first removal process comprises a dry etching process that is conducted in a substantially vertical direction. In some embodiments, a dry etchant is used during the first removal process to remove the hard mask structure 120 and the STI structure 110, whereas in other embodiments, more than one dry etchant may be used in the first removal process to remove the hard mask structure 120 and the STI structure 110.

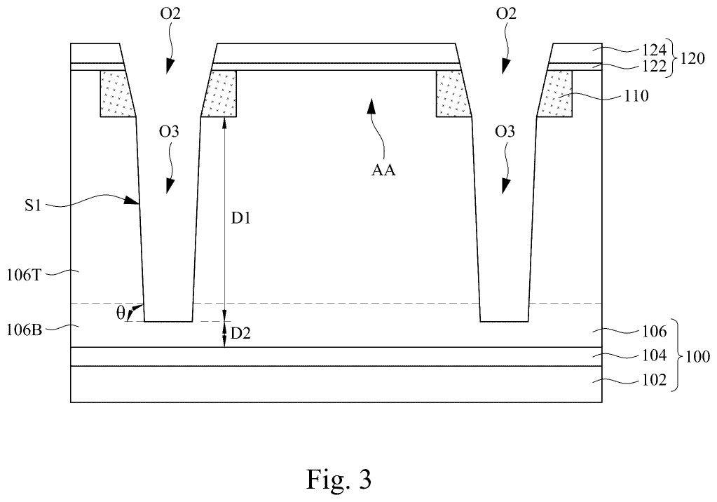

Reference is made to FIG. 3, in which FIG. 3 is a cross-sectional view following the cross-sectional view of FIG. 2B. A second removal process is performed to remove portions of the active semiconductor layer 106 of the SOI substrate 100 underlying the opening O2 of the STI structure 110, so as to form an opening O3 in the active semiconductor layer 106. In some embodiments, the second removal process is stopped prior to the opening O3 reaches the insulator layer 104. That is, once the second removal process is complete, the bottom end of the opening O3 is still higher than the top surface of the insulator layer 104. In some embodiments, the second removal process is performed to remove the active semiconductor layer 106 by a vertical depth D1, and the remaining portion of the active semiconductor layer 106 between the bottom end of the opening O3 and the top surface of the insulator layer 104 has a depth D2 therebetween. In some embodiments, the depth D1 is greater than the depth D2. For example, when the thickness of the active semiconductor layer 106 is about 4.5 μm, the depth D1 is about 4.0 μm and the depth D2 is about 0.5 μm. In some embodiments, once the second removal process is complete, the opening O3 has a substantially straight sidewall. In some embodiments, the straight sidewall of the opening O3 is a slanting sidewall, which forms an acute angle θ with a horizontal surface (e.g., the top surface of the insulator layer 104). In some embodiments, the acute angle θ is about 89.1 degree. However, in other embodiments, the sidewall of the opening O3 may be a vertical sidewall that is substantially vertical to with a horizontal surface (e.g., the top surface of the insulator layer 104). In some embodiments, the bottom end of the opening O3 may be lower than the top portion 106T of the active semiconductor layer 106.

In some embodiments, the second removal process is or comprises a dry etching process conducted in a substantially vertical direction. In some embodiments, a dry etchant is used during the second removal process to remove the active semiconductor layer 106. In other embodiments, more than one dry etchant may be used in the second removal process.

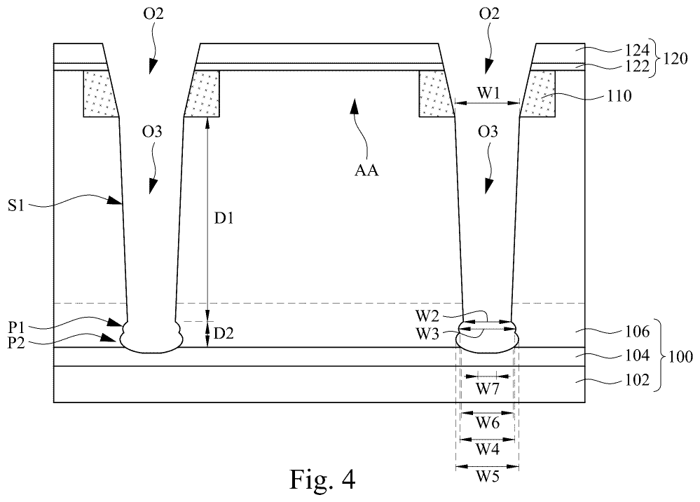

Reference is made to FIG. 4, in which FIG. 4 is a cross-sectional view following the cross-sectional view of FIG. 3. A third removal process is performed to further remove portions of the active semiconductor layer 106 of the SOI substrate 100 underlying the opening O3 of the STI structure 110, so as to extend the opening O3 in the active semiconductor layer 106 until the insulator layer 104 is exposed. In some embodiments, the opening O3 may slightly extend into the insulator layer 104 by, for example, about 700 Å.

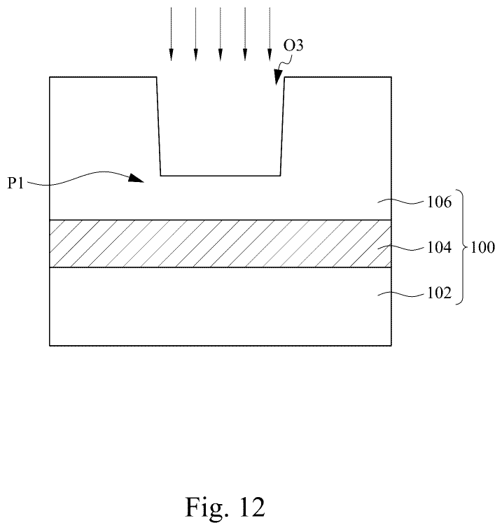

In some embodiments, the third removal process may be performed using a Bosch process, such that the bottom portion of the opening O3 may include a profile that is different from the top portion of the opening O3, the second and third removal processes will be discussed in more detail later (e.g., in FIGS. 12 to 15). Once the third removal process is complete, the opposite sidewalls of the opening O3 each may include a first protrusion portion P1 and a second protrusion portion P2 connected with each other. In some embodiments, the bottom end of the first protrusion portion P1 may be in contact with the top end of the second protrusion portion P2, and the bottom end of the second protrusion portion P2 may be substantially level with the top surface of the insulator layer 104. In some embodiments, the second protrusion portion P2 is connected to the top surface of the insulator layer 104.

In some embodiments, the first protrusion portion P1 and the second protrusion portion P2 are closer to the insulator layer 104 (or the bottom surface of the active semiconductor layer 106) than to the STI structure 110 (or the top surface of the active semiconductor layer 106). For example, the vertical distance between the top end of the first protrusion portion P1 and the STI structure 110 is the same as the depth D1 discussed above, and the vertical distance between the top end of the first protrusion portion P1 and the insulator layer 104 is the same the depth D2 as discussed above.

From another perspective, the opening O3 within the active semiconductor layer 106 may include a top with W1, the width of the opening O3 then decreases from the top with W1 to a width W2. Here, the position of the width W2 can be regarded as the top end of the first protrusion portion P1. The width of the opening O3 then increases from the width W2 to a width W3, and decreases from the width W3 to a width W4. Here, the position of the width W4 can be regarded as the bottom end of the first protrusion portion P1 and the top end of the second protrusion portion P2. Similarly, the width of the opening O3 then increases from the width W4 to a width W5, and then decreases from the width W5 to a width W6. Here, the position of the width W6 can be regarded as the bottom end of the second protrusion portion P2. The width of the opening O3 then decreases from the width W6 to a width W7. Here, the position of the width W7 can be regarded as the width of the bottom surface of the opening O3.

In some embodiments, the opposite sidewalls of the opening O3 each may include a straight portion S1 above the first protrusion portion P1. In some embodiments, the second protrusion portion P2 may extend beyond the first protrusion portion P1. That is, the outermost end of the second protrusion portion P2 may extend a farther lateral distance than the outermost end of the first protrusion portion P1. Stated another way, the width W5 is greater than the width W3.

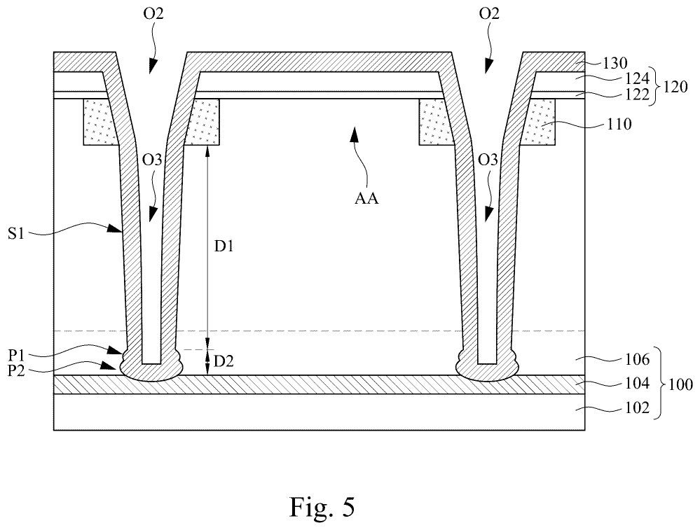

Reference is made to FIG. 5, in which FIG. 5 is a cross-sectional view following the cross-sectional view of FIG. 4. An isolation liner 130 is formed over the SOI substrate 100 and lining the opening O3 within the hard mask structure 120, the STI structure 110, the active semiconductor layer 106, and the insulator layer 104. In greater detail, the isolation liner 130 may extend from top surface of the hard mask structure 120, through sidewalls of the hard mask structure 120, the STI structure 110, and the active semiconductor layer 106, to top surface of the insulator layer 104. It is noted that the isolation liner 130 is formed lining the opening O3, and thus the isolation liner 130 may inherit the profile of the opening O3.

Accordingly, the isolation liner 130 may include similar sidewall profiles as the opening O3 as discussed in FIG. 4. In some embodiments, the isolation liner 130 is formed by a deposition process (e.g., CVD, PE-CVD, ALD, or the like). In some embodiments, the isolation liner 130 may comprise an oxide, such as, for example, silicon oxide. In other embodiments, the isolation liner 130 may comprise some other dielectric material such as silicon carbide, silicon oxide, or silicon oxynitride, for example.

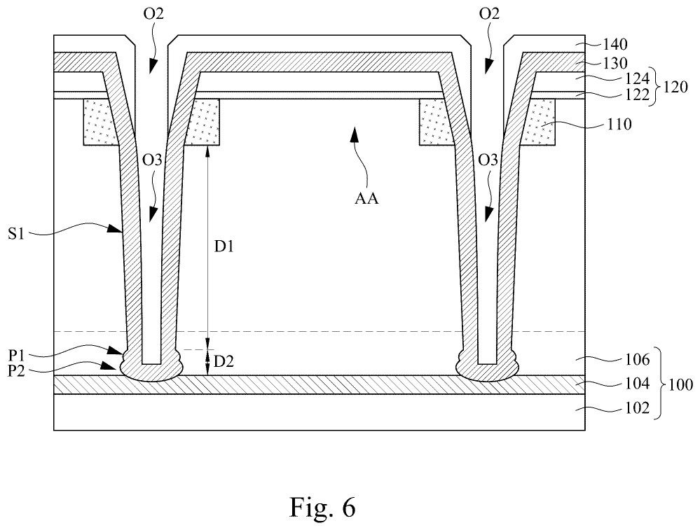

Reference is made to FIG. 6, in which FIG. 6 is a cross-sectional view following the cross-sectional view of FIG. 5. A protective layer 140 is formed over the isolation liner 130. In some embodiments, the protective layer 140 is formed with a selective manner, such that the protective layer 140 may cover top portions of the isolation liner 130, while leaving bottom portions of the isolation liner 130 exposed. In some embodiment, at least the bottom surface of the opening O3 is free of coverage by the protective layer 140. Stated another way, the horizontal portions of the isolation liner 130 extending along the top surface of the insulator layer 104 are fee of coverage by the protective layer 140. In some embodiments, the protective layer 140 may include undoped silicate glass (USG). In other embodiments, the protective layer 140 may comprise an oxide, such as, for example, silicon oxide. In some embodiments, the protective layer 140 may be made of a same material as the isolation liner 130. In other embodiments, the isolation liner 130 may comprise some other dielectric material such as silicon carbide, silicon oxide, or silicon oxynitride, for example.

In some embodiments, the deposition parameter of the protective layer 140, such as pressure, temperature, or flow rate of the precursors, can be controlled, such that the precursors of the protective layer 140 are hard to flow into the deep side of the opening O3. As a result, the protective layer 140 may include a higher deposition rate at the top portions of the isolation liner 130 than at the bottom portions of the isolation liner 130.

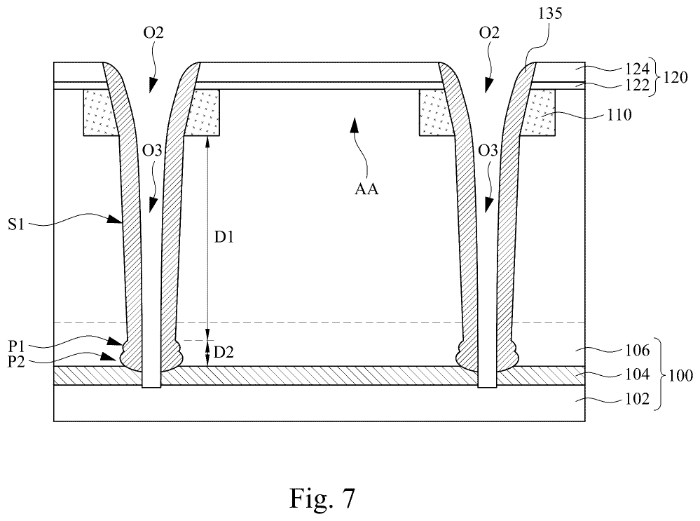

Reference is made to FIG. 7, in which FIG. 7 is a cross-sectional view following the cross-sectional view of FIG. 6. A fourth removal process is performed to remove portions of the isolation liner 130 through the opening O3, so as to form an opening O4 extending through the horizontal portions of the isolation liner 130 extending along the top surface of the insulator layer 104. The fourth removal process may continuously remove portions of the insulator layer 104 and the base semiconductor layer 102, such that the bottom end of the opening O4 extends into the base semiconductor layer 102. That is, the bottom end of the opening O4 may be lower than the bottom surface of the insulator layer 104. In some embodiments, the opening O4 may extend into the insulator layer 104 by, for example, about 300 Å.

On the other hand, the protective layer 140 and the horizontal portions of the isolation liner 130 extending along the top surface of the hard mask structure 120 may also be removed during the fourth removal process, such that the hard mask structure 120 may be exposed once the fourth removal process is complete. In some embodiments, due to the present of the protective layer 140, the protective layer 140 can act as a sacrificial layer to prevent over-etching to the hard mask structure 120. For example, if the protective layer 140 is absent, the fourth removal process will first remove the horizontal portions of the isolation liner 130 along the top surface of the hard mask structure 120 and the horizontal portions of the isolation liner 130 along the top surface of the insulator layer 104, such that the top surface of the hard mask structure 120 and the top surface of the insulator layer 104 will be exposed. When the fourth removal process continuously removes portions of the insulator layer 104 and the base semiconductor layer 102, the fourth removal process may unwantedly consume the exposed hard mask structure 120, which will adversely affect the following process.

As a result of the fourth removal process, vertical portions of the isolation liner 130 may remain in the opening O3, and the remaining vertical portions of the isolation liner 130 can be referred to as isolation liner 135. In some embodiments, the vertical portions of the isolation liner 130 may also be etched during the fourth removal process, and thus the remaining isolation liner 135 may taper upwardly.

In some embodiments, the fourth removal process comprises a dry etching process that is conducted in a substantially vertical direction. In some embodiments, a dry etchant is used during the fourth removal process to remove the protective layer 140, the isolation liner 130, the insulator layer 104, and the base semiconductor layer 102, whereas in other embodiments, more than one dry etchant may be used in the fourth removal process to remove the protective layer 140, the isolation liner 130, the insulator layer 104, and the base semiconductor layer 102.

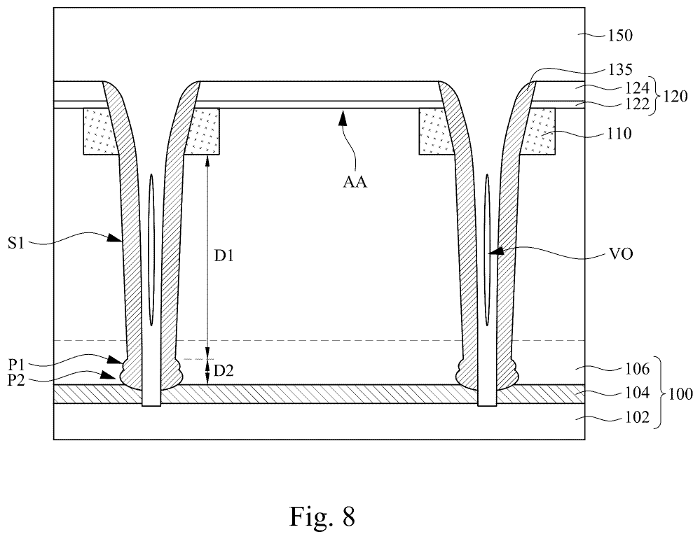

Reference is made to FIG. 8, in which FIG. 8 is a cross-sectional view following the cross-sectional view of FIG. 7. A conductive material 150 is formed over the SOI substrate 100 and filling the openings O3 and O4 (see FIG. 7). In some embodiments, the conductive material 150 may be a semiconductor material, such as polysilicon or some other suitable semiconductor material. In some embodiments, the conductive material 150 is formed by way of a deposition process (e.g., PVD, CVD, PE-CVD, low pressure CVD (LPCVD), ALD). In some embodiments, voids VO may be formed in the conductive material 150.

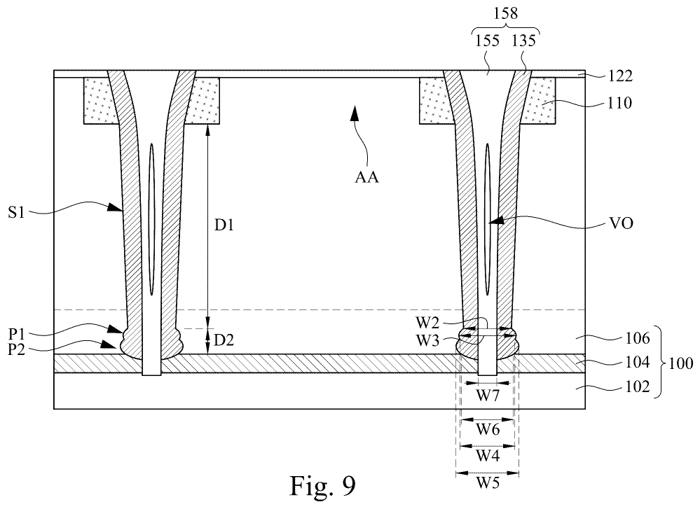

Reference is made to FIG. 9, in which FIG. 9 is a cross-sectional view following the cross-sectional view of FIG. 8. A planarization process, such as a CMP process, is performed to remove excess material of the conductive material 150. As a result, the remaining portion of the conductive material 150 may be referred to as conductive material 155. In some embodiments, the top surface of the conductive material 155 may be substantially level with the top surface of the isolation liner 135 as a result of the planarization process. However, the bottom surface of the conductive material 155 may be lower than the bottom surface of the isolation liner 135. In some embodiments, the isolation liner 135 and the conductive material 155 can be collectively referred to as a deep trench isolation (DTI) structure 158.

In some embodiments, the planarization process may be performed until the first dielectric layer 122 of the hard mask structure 120 is exposed. That is, the top surface of the conductive material 155 and the top surface of the isolation liner 135 may be substantially level with the top surface of the first dielectric layer 122. In such embodiments, the second dielectric layer 124 of the hard mask structure 120 may be removed as a result of the planarization process. In other embodiment, the planarization process may be performed until the active semiconductor layer 106 and the STI structure 110 are exposed. That is, the top surface of the conductive material 155 and the top surface of the isolation liner 135 may be substantially level with the top surfaces of the active semiconductor layer 106 and the STI structure 110. In such embodiments, the first dielectric layer 122 and the second dielectric layer 124 of the hard mask structure 120 may be removed as a result of the planarization process.

As discussed above, the DTI structure 158 is formed in the openings O3 and O4 (see FIG. 7), the DTI structure 158 may inherit the profile of the openings O3 and O4. For example, the isolation liner 135 of the DTI structure 158 (or the sidewall of the isolation liner 135 of the DTI structure 158) may include a first protrusion portion P1 and a second protrusion portion P2 connected with each other. In some embodiments, the bottom end of the first protrusion portion P1 may be in contact with the top end of the second protrusion portion P2, and the bottom end of the second protrusion portion P2 may be substantially level with the top surface of the insulator layer 104.

From another perspective, the DTI structure 158 within the active semiconductor layer 106 may include a top with W1, the width of the DTI structure 158 then decreases from the top with W1 to a width W2. Here, the position of the width W2 can be regarded as the top end of the first protrusion portion P1. The width of the DTI structure 158 then increases from the width W2 to a width W3, and decreases from the width W3 to a width W4. Here, the position of the width W4 can be regarded as the bottom end of the first protrusion portion P1 and the top end of the second protrusion portion P2. Similarly, the width of the DTI structure 158 then increases from the width W4 to a width W5, and then decreases from the width W5 to a width W6. Here, the position of the width W6 can be regarded as the bottom end of the second protrusion portion P2. The width of the DTI structure 158 then decreases from the width W6 to a width W7. Here, the position of the width W7 can be regarded as the bottom surface of the DTI structure 158.

In some embodiments, the isolation liner 135 of the DTI structure 158 (or the sidewall of the isolation liner 135 of the DTI structure 158) may include a straight portion S1 above the first protrusion portion P1. In some embodiments, the second protrusion portion P2 may extend beyond the first protrusion portion P1. That is, the outermost end of the second protrusion portion P2 may extend a farther lateral distance than the outermost end of the first protrusion portion P1. Stated another way, the width W5 is greater than the width W3.

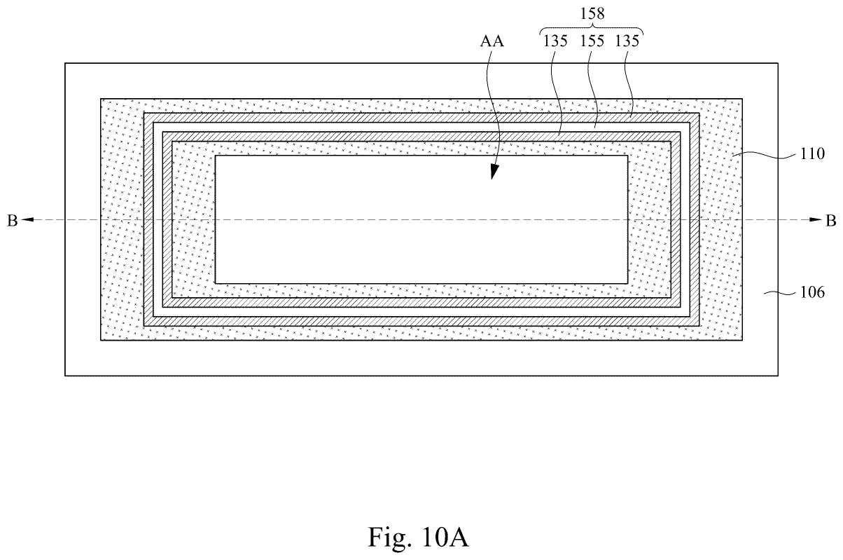

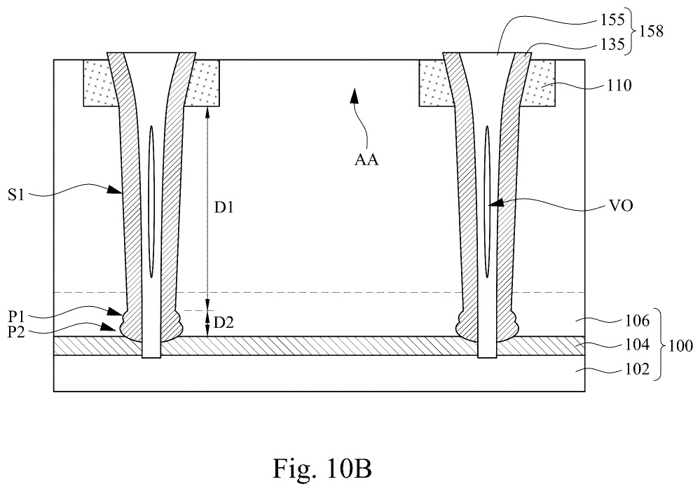

Reference is made to FIGS. 10A and 10B, in which FIG. 10A is a top view of a semiconductor device, and FIG. 10B is a cross-sectional view along line B-B of FIG. 10A. The first dielectric layer 122 is removed to expose the active semiconductor layer 106 and the STI structure 110. In greater detail, the active region AA of the active semiconductor layer 106 that is surrounded by the STI structure 110 and the isolation liner 135 may be exposed as a result of the removal of the first dielectric layer 122. In some embodiments, once the first dielectric layer 122 has been removed, the top surfaces of the isolation liner 135 and the conductive material 155 may be higher than the top surfaces of the active semiconductor layer 106 and the STI structure 110.

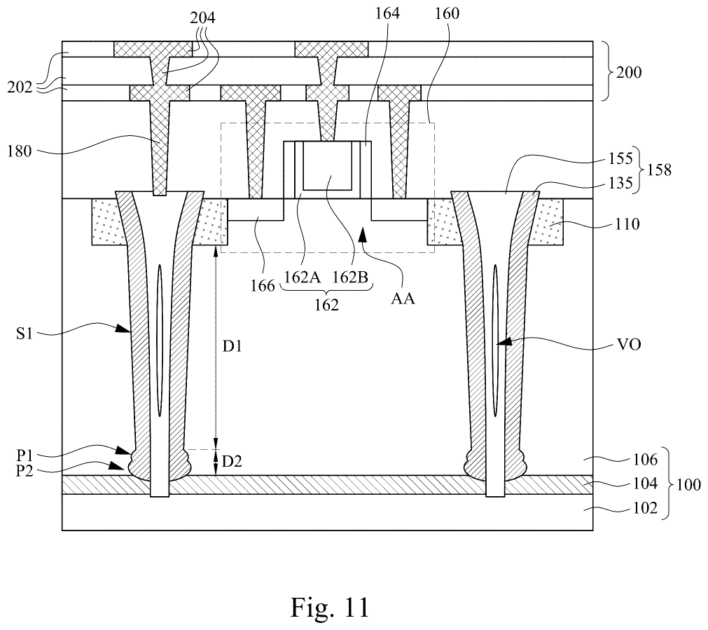

Reference is made to FIG. 11, in which FIG. 11 is a cross-sectional view following the cross-sectional view of FIG. 10B. A semiconductor device 160 is formed over the active region AA of the active semiconductor layer 106. In some embodiments, the semiconductor device 160 may be or comprise a transistor device such as a metal oxide semiconductor field effect transistor (MOSFET), whereas in other embodiments, for example, a bipolar complementary metal oxide semiconductor double diffused metal oxide semiconductor (BCD) device comprising multiple transistor devices. In some embodiments where the semiconductor device 160 is a transistor device, the semiconductor device 160 may be a planer FET, a fin-type FET (FinFET), a gate-all-around FET (GAA FET), a complementary FET (CFET), or other suitable transistor device.

In some embodiments, the semiconductor device 160 may include a gate structure 162 over the active region AA, gate spacers 164 on opposite sidewalls of the gate structure 162, and source/drain regions 166 over the active region AA and on opposite sides of the gate structure 162. In some embodiments, the gate structure 162 may include a gate dielectric layer 162A and a gate electrode 162B over the gate dielectric layer 162A.

In some embodiments, the gate dielectric layer 162A may include an interfacial layer and/or a high-k dielectric layer. The interfacial layer may be made of oxide, such as aluminum oxide (Al₂O₃), silicon oxide (SiO₂), or the like. The high-k dielectric layer may include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

In some embodiments, the gate electrode 162B may include polycrystalline-silicon (polysilicon), poly-crystalline silicon-germanium (poly-SiGe), metallic nitrides, metallic silicides, metallic oxides, and metals. In other embodiments, the gate electrode 162B may include a work function metal layer and a filling metal over the work function metal layer. The work function metal layer may include n-type or p-type work function layer. The filling metal may include tungsten (W), aluminum (Al), copper (Cu), or another suitable conductive material(s).

In some embodiments, the gate spacers 164 may be formed of silicon oxide, silicon nitride, silicon oxynitride, combinations thereof. In some embodiments, the source/drain regions 166 may be doped regions in the active semiconductor layer 106, or may be epitaxial structures over the active semiconductor layer 106. The source/drain regions 166 may include n-type or p-type dopants.

An interlayer dielectric (ILD) layer 170 is formed over the SOI substrate 100 and covering the semiconductor device 160. In some embodiments, the ILD layer 170 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

Conductive vias 180 are formed in the interlayer dielectric (ILD) layer 170. In some embodiments, the conductive vias 180 may include a conductive material such as aluminum, tungsten, copper, or some other suitable material. In some embodiments, the conductive vias 180 may be electrically connected to the gate structure 162 and the source/drain regions 166 of the semiconductor device 160 and the conductive material 155.

Afterwards, an interconnect structure 200 is formed over the ILD layer 170. The interconnect structure 200 may include a plurality of dielectric layers 202 stacked one above another, and may include a plurality of conductive features 204 (e.g., metal lines and metal vias) in the dielectric layers 202, respectively. In some embodiments, the conductive features 204 of the interconnect structure 200 may be electrically connected to the respective conductive vias 180.

In some embodiments, the dielectric layers 202 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The conductive features 204 may include a conductive material such as aluminum, tungsten, copper, or some other suitable material.

In some embodiments, the semiconductor device 160 may operate at high voltages. The DTI structure 158 and the STI structure 110 may collectively prevent the operating voltages of the semiconductor device 160 from leaking from the active region AA of the active semiconductor layer 106 to other devices arranged over the SOI substrate 100. Moreover, the interconnect structure 200 may be grounded to the base semiconductor layer 102 of the SOI substrate 100 through the conductive material 155 of the DTI structure 158, which improves the electrical isolation capability of the DTI structure 158 for the semiconductor device 160.

FIGS. 12 to 15 illustrate a method in various stages of forming a semiconductor device in accordance with some embodiments of the present disclosure. In greater detail, FIGS. 12 to 15 illustrate a detailed process for forming the opening O3 as discussed in FIGS. 3 and 4. It is noted that some elements of FIGS. 12 to 15 have been described above, and thus such elements will be labeled the same and relevant details will not be repeated for brevity.

Reference is made to FIG. 12, in which FIG. 12 shows the second removal process as discussed in FIG. 3. In FIG. 12, the second removal process is performed to remove portions of the active semiconductor layer 106 of the SOI substrate 100 to form an opening O3 in the active semiconductor layer 106. In some embodiments, the second removal process is a dry etching process, such as a plasma etching (e.g., reactive ion etching (RIE)). In some embodiments, the etchant used in the second removal process may be a fluorine-based plasma, such as SF₆ plasma. In some embodiments, the second removal process may be a continuous plasma etching, in which the etchant of the second removal process remain the same during the whole second removal process. That is, the second removal process is performed with a single etchant.

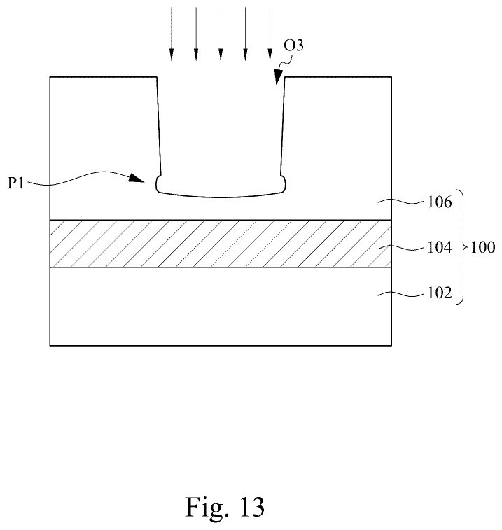

Reference is made to FIGS. 13 to 15, in which FIGS. 13 to 15 shows various steps of the third removal process as discussed in FIG. 4. In some embodiments, the third removal process is a dry etching process, such as a plasma etching (e.g., reactive ion etching (RIE)). However, different from the second removal process, the third removal process is a non-continuous plasma etching, in which the third removal process may be performed using different materials, which results in the opening O3 having the bottom profile as shown in FIG. 4. In some embodiment, the third removal process can also be referred to as a Bosch process.

In FIG. 13, the third removal process starts from a first step by performing an etching process. For example, an etchant gas is supplied into a process chamber. The etching process is performed by generating a plasma of the etchant gas. In some embodiments, the plasma of the etchant gas may be a fluorine-based plasma, such as SF₆ plasma. The plasma of the etchant gas can be generated in the process chamber by applying a bias voltage and an RF electromagnetic field, and thereby coupling the plasma power and the bias power to the etchant gas. The etchant gas is ionized to form a plasma containing etchant ions. The etchant ions are accelerated toward the opening O3 of the active semiconductor layer 106. Because of statistical distribution of velocity of the radicals in the plasma and the associated efficacy for forming volatile adsorbates, a lateral etch accompanies a vertical etch of the semiconductor material in the active semiconductor layer 106. As a result, the first protrusion portion P1 are formed in the opening O3 as a result of the first step of the third removal process.

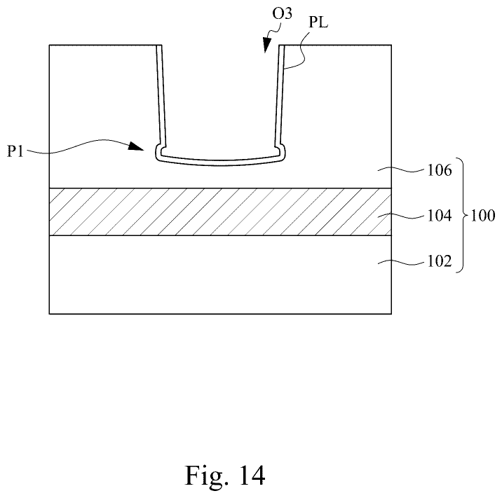

In FIG. 14, once the first step of FIG. 13 is complete, the third removal process proceeds to a second step by performing a deposition process. In some embodiments, a purging process may be performed to pump out the etchant gas of the first step from the process chamber, and a deposition gas is supplied into the process chamber. In some embodiments, the deposition gas includes a hydrofluorocarbon gas having a chemical formula of CₓH_{y}F_{z}. For example, the deposition gas may include C₄F₈. The deposition process is performed by generating a plasma of the deposition gas. The plasma of the deposition gas can be generated in the process chamber by applying a bias voltage and an RF electromagnetic field, and thereby coupling the plasma power and the bias power to the deposition gas. The deposition gas is ionized to form a plasma of hydrofluorocarbon ions. The hydrofluorocarbon ions are accelerated toward the the opening O3 of the active semiconductor layer 106 to deposit a hydrofluorocarbon polymer layer PL along sidewalls of the opening O3. Because of statistical distribution of velocity of the radicals in the plasma, the hydrofluorocarbon polymer layer PL is deposited as a conformal layer along the opening O3 as well as the first protrusion portion P1.

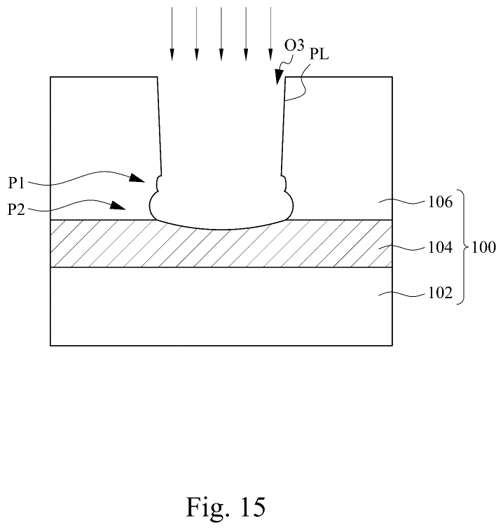

In FIG. 15, once the second step of FIG. 14 is complete, the third removal process proceeds to a third step by performing an etching process. In some embodiments, the etchant gas of the third step may be the same as the etchant gas of the first step as discussed in FIG. 13. For example, the etching process may also employ a plasma of a fluorine-containing etchant such as SF₆. Moreover, the parameters for generating the plasma of the etchant radicals and ions may be controlled such that etchant ions may be impinged toward the opening O3. During the third step, the hydrofluorocarbon polymer layer PL is etched anisotropically such that horizontal portions of the hydrofluorocarbon polymer layer 30 located at a bottom surface of the opening O3 may be etched, while portions of the hydrofluorocarbon polymer layer 30 located on the sidewalls of the opening O3 are not removed. The etching process continues after the bottom portion of the hydrofluorocarbon polymer layer PL is removed and a semiconductor surface of the active semiconductor layer 106 is physically exposed at the bottom of the opening O3. The etchant plasma commences etching of the semiconductor material of the active semiconductor layer 106 such that a vertical etch and a lateral etch of the semiconductor material of the active semiconductor layer 106 occur simultaneously, while a remaining portion of the hydrofluorocarbon polymer layer PL at the sidewalls of the opening O3 protect the semiconductor material around the remaining portion of the hydrofluorocarbon polymer layer PL. The opening O3 is extended downward to add a newly added cavity volume. As a result, the second protrusion portion P2 are formed in the opening O3 as a result of the third step of the third removal process. Moreover, the hydrofluorocarbon polymer layer PL along sidewalls of the opening O3 may also be consumed during the third step of the third removal process, and the third step of the third removal process may be stopped once the hydrofluorocarbon polymer layer PL is completely removed. In some embodiments, the insulator layer 104 may also be etched during the third step of the third removal process.

Once the third removal process is complete, the structure shown in FIG. 15 may undergo the processes as discussed in FIGS. 5 to 11, and the resulting structure is shown in FIG. 11.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments provide a structure and a method of a DTI structure. In greater detail, a removal process is performed to enlarge a bottom of the DTI trench, so as to create a double necking profile at the bottom of the DTI trench. Accordingly, the bottom thickness of the isolation liner of the DTI structure may be increased, and the isolation capability of the isolation liner at the bottom of the DTI structure may be improved. Moreover, the double necking profile may also smooth out the sharp angle of the bottom corner of the active semiconductor layer, and will reduce the corona discharge at the bottom corner of the active semiconductor layer. With such configuration, the current leakage may be reduced during high voltage operation of the semiconductor device, and thus the device performance will be improved.

In some embodiments of the present disclosure, a semiconductor device includes substrate. The substrate includes a base semiconductor layer, an insulator layer over the base semiconductor layer, and an active semiconductor layer over the base semiconductor layer, wherein the active semiconductor layer has an active region. A deep trench isolation (DTI) structure is in the substrate and adjacent to the active region, wherein in a cross-sectional view, a sidewall of the DTI structure comprises a first protrusion portion and a second protrusion portion below the first protrusion portion.

In some embodiments, the sidewall of the DTI structure comprises a straight portion above the first protrusion portion.

In some embodiments, the second protrusion portion is connected to a top surface of the insulator layer of the substrate.

In some embodiments, an outermost end of the second protrusion portion extend a farther lateral distance than an outermost end of the first protrusion portion.

In some embodiments, the first protrusion portion and the second protrusion portion are closer to a bottom surface of the active semiconductor layer of the substrate than to a top surface of the active semiconductor layer.

In some embodiments, the DTI structure comprises a conductive material and an isolation liner surrounding the conductive material, wherein the sidewall of the DTI structure is defined by the isolation liner.

In some embodiments, the conductive material extends through the insulator layer of the substrate to the base semiconductor layer of the substrate.

In some embodiments of the present disclosure, a semiconductor device includes substrate. The substrate includes a base semiconductor layer, an insulator layer over the base semiconductor layer, and an active semiconductor layer over the base semiconductor layer, wherein the active semiconductor layer has an active region. A deep trench isolation (DTI) structure is in the substrate and adjacent to the active region, wherein the DTI structure comprises a first portion, a second portion below the first portion, wherein a width of the second portion increases from a first width to a second width, and then decreases from the second width to a third width, and a third portion below the second portion, wherein a width of the third portion increases from the third width to a fourth width, and then decreases from the fourth width to a fifth width.

In some embodiments, a depth of the first portion is greater than a depth of the second portion and a depth of the third portion.

In some embodiments, the second width is greater than the fourth width.

In some embodiments, the third portion is at a top surface of the insulator layer of the substrate.

In some embodiments, in a top view, the DTI structure surrounds the active region.

In some embodiments, a shallow trench isolation structure (STI) in the substrate, wherein the DTI structure extends through the STI structure.

In some embodiments, the DTI structure comprises a polysilicon layer in contact with the base semiconductor layer and an isolation liner surrounding the polysilicon layer.

In some embodiments, the semiconductor device further includes a transistor over the active region of the active semiconductor layer and an interconnect structure over the transistor, wherein the interconnect structure is electrically connected with the DTI structure.

In some embodiments of the present disclosure, a method includes performing a first removal process to a substrate having a base semiconductor layer, an insulator layer over the base semiconductor layer, and an active semiconductor layer over the base semiconductor layer, so as to form an opening in the active semiconductor layer of the substrate; performing a second removal process to extend the opening in the active semiconductor layer until the insulator layer of the substrate is exposed, wherein a sidewall of the opening has at least one protrusion portion as a result of the second removal process; forming an isolation liner along the opening; performing a third removal process to remove portions of the isolation liner and the insulator layer until the base semiconductor layer is exposed; and forming a conductive material in the opening.

In some embodiments, the second removal process is performed such that the sidewall of the opening has a first protrusion portion and a second protrusion portion below the first protrusion portion.

In some embodiments, the third removal process comprises performing a fist etching process to form the first protrusion portion of the sidewall of the opening; performing a deposition process to form a polymer layer lining the sidewall of the opening; and performing a second etching process to form the second protrusion portion of the sidewall of the opening, wherein the polymer layer is removed once the second etching process is complete.

In some embodiments, the method further includes prior to performing the third removal process, forming a protective layer covering a top portion of the isolation liner, while leaving a bottom portion of the isolation liner exposed.

In some embodiments, the method further includes forming a shallow trench isolation (STI) structure in the substrate prior to performing the first removal process, wherein the first removal process is performed through the STI structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate, comprising:
a base semiconductor layer;
an insulator layer over the base semiconductor layer; and
an active semiconductor layer over the base semiconductor layer, wherein the active semiconductor layer has an active region; and
a deep trench isolation (DTI) structure in the substrate and adjacent to the active region, wherein in a cross-sectional view, a sidewall of the DTI structure comprises a first protrusion portion and a second protrusion portion below the first protrusion portion.

2. The semiconductor device of claim 1, wherein the sidewall of the DTI structure comprises a straight portion above the first protrusion portion.

3. The semiconductor device of claim 1, wherein the second protrusion portion is connected to a top surface of the insulator layer of the substrate.

4. The semiconductor device of claim 1, wherein an outermost end of the second protrusion portion extends a farther lateral distance than an outermost end of the first protrusion portion.

5. The semiconductor device of claim 1, wherein the first protrusion portion and the second protrusion portion are closer to a bottom surface of the active semiconductor layer of the substrate than to a top surface of the active semiconductor layer.

6. The semiconductor device of claim 1, wherein the DTI structure comprises:
a conductive material; and
an isolation liner surrounding the conductive material, wherein the sidewall of the DTI structure is defined by the isolation liner.

7. The semiconductor device of claim 6, wherein the conductive material extends through the insulator layer of the substrate to the base semiconductor layer of the substrate.

8. A semiconductor device, comprising:
a substrate, comprising:
a base semiconductor layer;
an insulator layer over the base semiconductor layer; and
an active semiconductor layer over the base semiconductor layer, wherein the active semiconductor layer has an active region; and
a deep trench isolation (DTI) structure in the substrate and adjacent to the active region, wherein the DTI structure comprises:
a first portion;
a second portion below the first portion, wherein a width of the second portion increases from a first width to a second width, and then decreases from the second width to a third width; and
a third portion below the second portion,, wherein a width of the third portion increases from the third width to a fourth width, and then decreases from the fourth width to a fifth width.

9. The semiconductor device of claim 8, wherein a depth of the first portion is greater than a depth of the second portion and a depth of the third portion.

10. The semiconductor device of claim 8, wherein the second width is greater than the fourth width.

11. The semiconductor device of claim 8, wherein the third portion is at a top surface of the insulator layer of the substrate.

12. The semiconductor device of claim 8, wherein in a top view, the DTI structure surrounds the active region.

13. The semiconductor device of claim 8, further comprising a shallow trench isolation structure (STI) in the substrate, wherein the DTI structure extends through the STI structure.

14. The semiconductor device of claim 8, wherein the DTI structure comprises:
a polysilicon layer in contact with the base semiconductor layer; and
an isolation liner surrounding the polysilicon layer.

15. The semiconductor device of claim 8, further comprising:
a transistor over the active region of the active semiconductor layer; and
an interconnect structure over the transistor, wherein the interconnect structure is electrically connected with the DTI structure.

16. A method, comprising:
performing a first removal process to a substrate having a base semiconductor layer, an insulator layer over the base semiconductor layer, and an active semiconductor layer over the base semiconductor layer, so as to form an opening in the active semiconductor layer of the substrate;
performing a second removal process to extend the opening in the active semiconductor layer until the insulator layer of the substrate is exposed, wherein a sidewall of the opening has at least one protrusion portion as a result of the second removal process;
forming an isolation liner along the opening;
performing a third removal process to remove portions of the isolation liner and the insulator layer until the base semiconductor layer is exposed; and
forming a conductive material in the opening.

17. The method of claim 16, wherein the second removal process is performed such that the sidewall of the opening has a first protrusion portion and a second protrusion portion below the first protrusion portion.

18. The method of claim 17, wherein the third removal process comprises:
performing a fist etching process to form the first protrusion portion of the sidewall of the opening;
performing a deposition process to form a polymer layer lining the sidewall of the opening; and
performing a second etching process to form the second protrusion portion of the sidewall of the opening, wherein the polymer layer is removed once the second etching process is complete.

19. The method of claim 16, further comprising, prior to performing the third removal process, forming a protective layer covering a top portion of the isolation liner, while leaving a bottom portion of the isolation liner exposed.

20. The method of claim 16, further comprising forming a shallow trench isolation (STI) structure in the substrate prior to performing the first removal process, wherein the first removal process is performed through the STI structure.
